(19) United States
(12) Patent Application Publication
(10) Pub. No.: US 2025/0271772 A1
(43) Pub. Date: Aug. 28, 2025

(54) PROJECTION EXPOSURE APPARATUS WITH MANIPULATORS

(71) Applicant: Carl Zeiss SMT GmbH, Oberkochen (DE)

(72) Inventors: Malte LANGENHORST, Aalen (DE); Christian LUTZWEILER, Muenchen (DE); Jonas UMLAUFT, Regensburg (DE); Stratis TZOUMAS, Pullach im lsartal (DE)

(21) Appl. No.: 19/206,417

(22) Filed: May 13, 2025

Related U.S. Application Data
(63) Continuation of application No. PCT/EP2023/082252, filed on Nov. 17, 2023.

(30) Foreign Application Priority Data
Nov. 22, 2022 (GR) 20220100960
Dec. 23, 2022 (DE) 10 2022 004 902.3

(51) Int. Cl. G03F 7/00; G02B 27/00

(52) U.S. Cl. CPC G03F 7/70266; G02B 27/0025; G03F 7/70316; G03F 7/70504; G03F 7/70525; G03F 7/70591; G03F 7/70891

(57) ABSTRACT

A microlithographic projection exposure apparatus comprises a projection lens having a plurality of optical elements for imaging mask structures and a plurality of manipulators, each of which is assigned to one of the optical elements and configured to change an optical effect of the assigned optical element by manipulating a property of the optical element along a travel. Furthermore, the projection exposure apparatus comprises a manipulator controller which comprises an algorithm for ascertaining a travel command with travel specifications for the manipulators for correcting a wavefront deviation of the projection lens. The algorithm is configured to ascertain an associated wavefront change of the projection lens from a travel vector with a set of manipulator travels using a neural network and to determine the travel command using an ascertainment result of the neural network from the wavefront deviation.

### CROSS-REFERENCE TO RELATED APPLICATIONS

The present application is a continuation of, and claims benefit under 35 USC 120 to, international application No. PCT/EP2023/082252, filed Nov. 11, 2023, which claims benefit under 35 USC 119 of German Patent Application No. 10 2022 004 902.3 filed Dec. 23, 2022, and Greek Patent Application No. 2022 0100 960, filed Nov. 22, 2022. The entire disclosure of each of these applications is incorporated by reference herein.

### FIELD

The disclosure relates to a microlithographic projection exposure apparatus and to a method of operating such a projection exposure apparatus.

### BACKGROUND

A projection lens with wavefront aberrations that are as small as reasonably possible is used to try to ensure imaging of the mask structures on the wafer as precisely as reasonably possible. Thus, projection lenses are typically equipped with manipulators which make it possible to minimize wavefront errors by way of correction measures in the form of state changes in individual optical elements of the projection lens. Examples of such state changes include applying heat and/or cold to the optical element, deforming the optical element, and/or changing the position of the relevant optical element in one or more of the six rigid body degrees of freedom.

To this end, the aberration characteristic of the projection lens is usually measured regularly and, if appropriate, changes in the aberration characteristic between the individual measurements are determined by simulation. In this regard, for example, lens element heating effects can be taken into account computationally. The manipulator changes to be implemented for the purpose of correcting the aberration characteristic are calculated using a travel-generating optimization algorithm, which is also referred to as “manipulator change model”. In the process, a correction command specifying the manipulator changes to be implemented is generated on the basis of measurement values from a wavefront sensor. By way of example, such optimization algorithms are described in WO 2010/034674 A1.

However, correction commands that are generated in conventional fashion using optimization algorithms are often relatively imprecise and often may not fully satisfy increasing demands in respect of the correction accuracy for the imaging behaviour of the projection exposure apparatus. When FE models, i.e. models based on finite element methods, are used, the correction commands can be ascertained with relatively high accuracy, but it will take a relatively long time. As a result, the correction command update rate is generally too low, and the average correction accuracy over time consequently continues to be generally too low.

### SUMMARY

The disclosure seeks to provide a projection exposure apparatus and a method of operating such a projection exposure apparatus, with which existing issues may be resolved and with which, for example, it may be possible to attain a relatively high correction accuracy for the imaging behaviour of the projection exposure apparatus while at the same time having a relatively high update rate of a correction command generated for the purpose of correction.

In an aspect, the disclosure provides a microlithographic projection exposure apparatus which comprises a projection lens with a plurality of optical elements for imaging mask structures and a plurality of manipulators, each of which is assigned to one of the optical elements and configured to change an optical effect of the assigned optical element by manipulating a property of the optical element along a travel. Furthermore, the projection exposure apparatus comprises a manipulator controlle, which comprises an algorithm for ascertaining a travel command with travel specifications for the manipulators for correcting a wavefront deviation of the projection lens. The algorithm is configured to ascertain an associated wavefront change of the projection lens from a travel vector with a set of manipulator travels using a neural network, and to determine the travel command using an ascertainment result of the neural network from the wavefront deviation.

A neural network is a machine learning method based on artificial intelligence. It is taught or trained using a multiplicity of training data sets, which each comprise manipulator travels and associated wavefront changes of the projection lens. These training data sets can be ascertained by simulations and/or measurements.

By using the aforementioned neural network, it is possible to execute the algorithm with relatively high precision and at the same time relatively high speed and thus achieve an improved correction accuracy of the imaging behaviour of the projection exposure apparatus with a simultaneously relatively high update rate of the travel command or a specific correction accuracy with an improved update rate. The algorithm may, for example, be an optimization algorithm or be configured to ascertain the travel command from the wavefront deviation using a further neural network.

According to an embodiment, the algorithm is configured to determine the travel command by optimizing a target function and to use the ascertainment result of the neural network in the optimization.

According to an embodiment, the target function has a nonlinear sensitivity which defines a relationship between the travel vector and the associated wavefront change of the projection lens, wherein the ascertainment result comprises a gradient of the nonlinear sensitivity. In other words, the ascertainment result includes one or more local gradient values of a locally linearized form of the nonlinear sensitivity that can be used by the optimization algorithm.

According to an embodiment, the ascertainment result further comprises a value of the nonlinear sensitivity. This value indicates a wavefront change value.

For example, the gradient is assigned to a vector value of the travel vector and the value of the nonlinear sensitivity is assigned to the same vector value of the travel vector. The vector value is understood to mean the totality of the values of the vector elements of the travel vector, i.e. the vector value itself is a vector. The wavefront value can be an individual scalar value, such as the value of a selected Zernike coefficient, or a plurality of scalar values.

According to an embodiment, the target function comprises not only the nonlinear sensitivity, but also the wavefront deviation to be corrected, and for example at least one regularization term.

According to an embodiment, the algorithm is configured as a gradient-based method, such as as a gradient descent method.

According to an embodiment, the algorithm is configured as a statistical search method or as a deterministic, gradient-free algorithm, for example as a Nelder-Mead method, and the at least one characteristic property comprises a value of the wavefront change.

Statistical search methods and deterministic, gradient-free algorithms are generally known. These do not require gradient values for the sensitivity. In the Nelder-Mead method, the respective wavefront value is determined in a first iteration step for a specified number of, e.g. ten, widely spread vector values of the travel vector. A vector value is selected therefrom and in the following iteration step, the respective wavefront value is determined again for a specified number of, e.g. ten, vector values. These vector values are no longer as widely spread as the vector values of the first iteration step, but lie within a narrow vicinity of the selected vector value. Further iteration steps are performed analogously, i.e. the spread of the vector values is narrower with each step than in the previous step.

According to an embodiment, the algorithm is configured to effect the optimization of the target function iteratively and to update the ascertainment result with each iteration and to determine the at least one characteristic property of the target function based on the updated ascertainment result of the neural network.

According to an embodiment, the manipulator controller is configured to ascertain training data sets generated using the ascertainment result of the neural network, hereinafter also referred to as the first neural network, and to train therewith a further neural network, wherein the algorithm is configured to ascertain the travel command from the wavefront deviation using the further neural network.

According to an embodiment, the manipulator controller is configured to determine the training data sets by optimizing a target function and to use the ascertainment result of the first neural network in the optimization. For example, the target function has a nonlinear sensitivity which defines a relationship between the travel vector and the associated wavefront change of the projection lens, wherein the ascertainment result comprises a gradient of the nonlinear sensitivity. In other words, the ascertainment result comprises one or more local gradient values of a locally linearized form of the nonlinear sensitivity. The ascertainment result can further comprise a value of the nonlinear sensitivity. This value indicates a wavefront change value.

According to an embodiment, boundary conditions for the travel command ascertained using the further neural network are created based on the training data sets. The boundary conditions are implicitly trained.

According to an embodiment, at least a part of the manipulators is assigned to the same optical element and configured to change a temperature of different sections of this optical element. The assigned manipulators are for example heating devices, so-called sector heaters. Alternatively, cooling devices can be used. According to a further embodiment, the manipulators are assigned to different optical elements and the travel command determined by the manipulator controller includes manipulator travels for the manipulators of the different optical elements. In this case, a part of the manipulators can be assigned to the same optical element or in each case a plurality of manipulators can be assigned to different optical elements.

According to an embodiment, the projection exposure apparatus further comprises a wavefront measurement device for ascertaining the desired correction on the wavefront. Alternatively or additionally, the projection exposure apparatus may also comprise a simulation device for ascertaining the desired correction using simulation. Measurement values from various sensors, e.g. temperature sensors at the optical elements, and/or exposure parameter values, such as intensity values of the exposure radiation, settings of the illumination setting and/or the layout of the exposed mask can be taken into account in the simulation.

According to an embodiment, the projection exposure apparatus has an operating wavelength in the extreme ultraviolet (EUV) wavelength range or deep ultraviolet (DUV) wavelength range. This means that in the case of the DUV wavelength range, for example, the operating wavelength is about 365 nanomters (nm), about 248 nm or about 193 nm, and in the case of the EUV wavelength range, for example, the operating wavelength is less than 100 nm, for example about 13.5 nm or about 6.8 nm.

In an aspect, the disclosure provides a method of operating a microlithographic projection exposure apparatus, which comprises a projection lens having a plurality of optical elements for imaging mask structures, and a plurality of manipulators. The manipulators are each assigned to one of the optical elements and configured to change an optical effect of the assigned optical element by manipulating a property of the optical element along a travel. The method comprises determining a wavefront deviation of the projection lens, ascertaining a wavefront change of the projection lens from a travel vector with a set of manipulator travels using a neural network, and determining a travel command with travel specifications for the manipulators from the wavefront deviation using an ascertainment result of the neural network.

The neural network can be part of the projection exposure apparatus. Alternatively, it can be executed on a separate computing unit and the ascertainment result is then, for example, made available to a manipulator controller of the projection exposure apparatus for determining the travel command.

According to an embodiment, a target function is optimized during the determination of the travel command, and the ascertainment result of the neural network is used in the optimization.

According to an embodiment, training data sets are ascertained using the ascertainment result of the neural network and a further neural network is trained therewith, by which the travel command is ascertained from the wavefront deviation.

The features specified regarding the embodiments, exemplary embodiments or embodiment variants, etc. listed above of the projection exposure apparatus according to the disclosure can be transferred accordingly to the method according to the disclosure and vice versa. These and certain other features of the embodiments according to the disclosure will be explained in the description of the figures and in the claims. The individual features can be implemented, either separately or in combination, as embodiments of the disclosure. Furthermore, they can describe embodiments which are independently protectable and protection for which is claimed only during or after dependency of the application, as the case may be.

### BRIEF DESCRIPTION OF THE DRAWINGS

The aforementioned features and further features of the disclosure will be illustrated in the following detailed description of exemplary embodiments according to the disclosure or of embodiments with reference to the attached schematic drawings, in which:

FIG. 1 shows an exemplary embodiment according to the disclosure of a microlithographic projection exposure apparatus with manipulators for respectively changing an optical effect of an assigned optical element and with a manipulator controller, which comprises an algorithm for ascertaining a travel command for the manipulators;

FIG. 2 shows a first embodiment of the manipulator controller of the projection exposure apparatus according to FIG. 1; and

FIG. 3 shows a second embodiment of the manipulator controller of the projection exposure apparatus according to FIG. 1.

### DETAILED DESCRIPTION OF EXAMPLE EMBODIMENTS

In the exemplary embodiments or embodiments or embodiment variants described below, elements which are functionally or structurally similar to one another are provided with the same or similar reference signs as far as reasonably possible. Therefore, for understanding the features of the individual elements of a specific exemplary embodiment, reference should be made to the description of other exemplary embodiments or the general description of the disclosure.

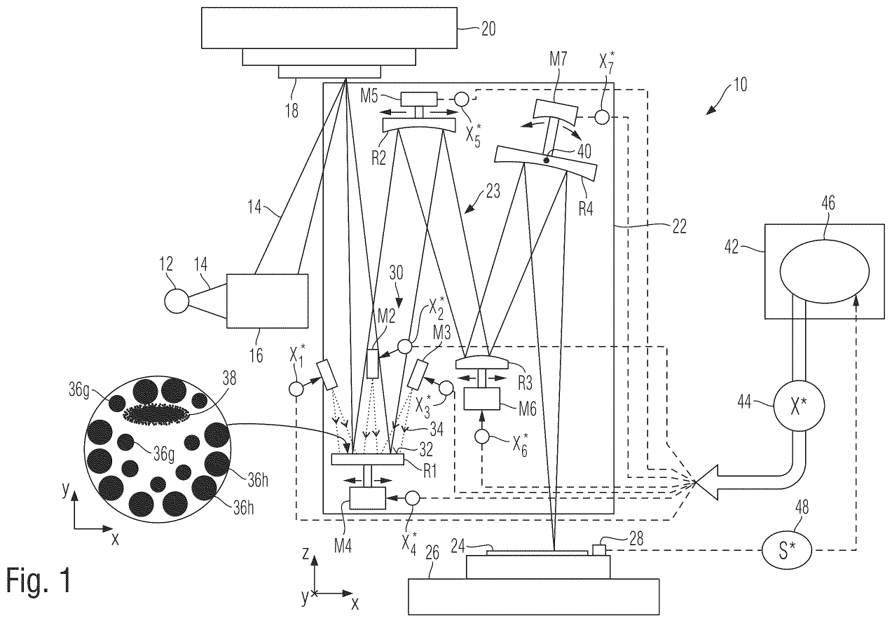

In order to facilitate the description, a Cartesian xyz-coordinate system is indicated in the drawing, from which system the respective positional relationship of the components illustrated in the figures is evident. In FIG. 1, the y-direction runs perpendicular to the drawing plane and into it, while the x-direction runs to the right and the z-direction to the top.

FIG. 1 shows an embodiment according to the disclosure of a microlithographic projection exposure apparatus 10, which is configured to be operated via an embodiment of a method according to the disclosure. The present embodiment of the projection exposure apparatus 10 is designed for operation in the EUV wavelength range, i.e. with electromagnetic radiation having a wavelength of less than 100 nm, such as a wavelength of about 13.5 nm or about 6.8 nm. All optical elements in the exposure beam path are embodied as mirrors as a result of this operating wavelength. In an alternative embodiment, the projection exposure apparatus 10 is designed for operation in the DUV wavelength range. In this case, the operating wavelength can be, for example, at approximately 365 nm, at approximately 248 nm, or at approximately 193 nm, and at least some of the optical elements in the exposure beam path are embodied as lens elements.

The projection exposure apparatus 10 according to FIG. 1 comprises an exposure radiation source 12 for generating exposure radiation 14. In the present case, the exposure radiation source 12 is embodied as an EUV source and can comprise, for example, a plasma radiation source. The exposure radiation 14 first passes through an illumination system 16 and is directed by the latter onto a mask 18.

The illumination system 16 is configured to generate different angular distributions of the exposure radiation 14 incident on the mask 18. The illumination system 16 configures the angular distribution of the exposure radiation 14 incident on the mask 18 depending on an illumination setting desired by the user. Examples of illumination settings that can be chosen include a so-called dipole illumination, an annular illumination and a quadrupole illumination.

The mask 18 has mask structures to be imaged on a substrate 24 in the form of a wafer and is displaceably mounted on a mask displacement stage 20. As illustrated in FIG. 1, the mask 18 can be embodied as a reflection mask or, alternatively, be configured as a transmission mask. In the embodiment according to FIG. 1, the exposure radiation 14 is reflected at the mask 18 and thereupon passes through a projection lens 22 configured to image the mask structures onto the substrate 24. The exposure radiation 14 is guided in an exposure beam path 23 within the projection lens 22 using a multiplicity of mirrors.

The substrate 24 is displaceably mounted on a substrate displacement stage 26. The projection exposure apparatus 10 can be embodied as a so-called scanner or a so-called stepper. A wavefront sensor 28 for measuring a wavefront deviation 48 of the projection lens 22, denoted by S*, during breaks in the exposure is arranged on the substrate displacement stage 26.

In the embodiment according to FIG. 1, the projection lens 22 has four optical elements in the form of mirrors or reflective elements R1 to R4. As mentioned above, the projection lens may also contain lens elements as optical elements in another embodiment. The mirror R1 arranged first in the beam path of the projection lens 22 is assigned a manipulation device 30 for the deformation of its mirror surface 32, which manipulation device 30 comprises a plurality of manipulators, each in the form of a heating device. In FIG. 1, three manipulators M1 to M3 are illustrated as heating devices by way of example in this respect. As explained in more detail below, the number of heating devices and thus manipulators of the manipulation device 30 may be greater or smaller.

The heating devices in the form of manipulators M1 to M3 serve as so-called sector heaters for the respective heating of a sector or section of the mirror surface 32 of the mirror R1. In the embodiment shown, the heating devices are for this purpose each configured as heating radiators and arranged at a specific distance from the mirror surface 32 for the respective irradiation of a respective section of the mirror surface 32 with heating radiation 34.

The heating radiation 34 can be radiated in a locally varying manner or locally evenly onto the mirror surface 32 from the respective heating device, such that either a locally varying or a uniform temperature can be set on the mirror surface 32.

To the left of the mirror R1, an example of a radiation distribution generated using the manipulation device 30 on the mirror surface 32 is shown, with which a corresponding temperature distribution with different temperatures in different local zones of the mirror surface 32, i.e. in different sections of the optical element in the form of the mirror R1, is obtained. Large circles each symbolize a local zone 36h with a high intensity of irradiation, and small circles each symbolize a local zone 36g with a lower intensity.

An exemplary cross section 38 of the exposure beam path 23, which is asymmetric in the depicted case, is likewise depicted. The exposure radiation 14 also leads to a temperature increase—unwanted in this case—in the region of the cross section 38. Such an increase in temperature changes the topography of the mirror surface 32. Changes in the mirror surface 32 induced by the exposure radiation 14 can be compensated for by a suitable irradiation of the mirror surface 32 using the manipulation device 30.

Alternatively or additionally, electric heating elements can be integrated into the substrate of the mirror R1. Using these heating elements, it is possible alternatively to the manipulation device 30 or in combination with the latter, to heat at least one region of the mirror surface 32 and thus to set a locally varying or a uniform temperature on the mirror surface 32. Further, or alternatively, cooling elements may be integrated into the substrate of the mirror R1 to set a locally varying or uniform temperature on the mirror surface 32. According to further embodiments (not illustrated), further ones of the mirrors R2 to R4 may be provided with heating and/or cooling manipulators. A relevant travel command for the heating/cooling manipulator system of each individual mirror can be modelled using a separate neural network, as described below with reference to the heating manipulators M1 to M3 of the mirror R1.

In the embodiment shown, the projection lens 22 has further manipulators M4 to M7. However, these manipulators are optional, i.e. exemplary embodiments according to the disclosure in which the manipulators M4 to M7 are not present are conceivable. In the present embodiment, the mirror R1 is again movably mounted. For this purpose, the manipulator M4 is assigned to the former. This manipulator allows a displacement of the mirror R1 in the x- and y-directions and thus substantially parallel to the plane in which the mirror surface 28 is located.

The mirrors R2 and R3 in the present embodiment are likewise displaceably mounted parallel to their respective mirror surfaces. For this purpose, the manipulators M5 and M6, which are configured similarly to the manipulator M4, are assigned to the mirrors R2 and R3. The manipulator M7 is assigned to the mirror R4. Thus, the mirror R4 can be tilted by being rotated about a tilt axis 40, which is disposed parallel to the y-axis and extends parallel to the optical surface of R4. This allows the angle of the mirror surface of R4 to be changed in relation to the incident exposure radiation 14.

Generally speaking, the manipulators M1 to M7 form a manipulator system of the projection lens 22 for changing the optical properties of the projection lens 22. The manipulator system has a multiplicity of manipulator degrees of freedom, wherein a single manipulator degree of freedom can be defined by an adjustment of one of the manipulators M1 to M3 designed as actuators or by one of the mirrors R1 to R4 being displaced or tilted using the manipulators M4 to M7. In addition to the manipulator degrees of freedom provided by the manipulators M1 to M7, further manipulator degrees of freedom, for example a tilt of the mirrors R1 to R3 and/or a displacement of the mirror R4, may be provided.

The projection exposure apparatus 10 further comprises a manipulator controller 42 for controlling, depending on the embodiment, at least the manipulation device 30 with the manipulators M1 to M3, and optionally further manipulators in the form of a heating device, and also for example the manipulators M4 to M7. An embodiment variant in which all manipulators M1 to M7 are controlled by the manipulator controller 42 is described below. For this purpose, the manipulator controller 42 generates a travel command X*, which is denoted by the reference sign 44.

The travel command 44 represents a vector whose vector elements comprise travel specifications xᵢ* for the travels xᵢ of the individual manipulators M1 to M7, to be precise a travel specification x₁* for the travel x₁ of the manipulator M1, travel specification x₂* for the travel x₂ of the manipulator M2, etc.

The manipulator controller 42 generates the travel command 44 using an algorithm 46 for correcting the wavefront deviation S* ascertained by the wavefront sensor 28 (cf. reference sign 48). In other words, the travel command 44 generated by the manipulator controller 42 serves to make a desired correction to the wavefront of the projection lens 22 that is opposite to the ascertained wavefront deviation S*. The wavefront deviation 48 of the projection lens 22 denotes a deviation of the wavefront of the projection lens 22 from a desired wavefront.

The desired wavefront may be defined according to one embodiment by spherical wavefronts present at the individual field points in the image plane of the projection lens 22, wherein the envelope of these wavefronts along the image plane results in a plane wavefront. As mentioned above, the wavefront deviation 48 is measured using the wavefront sensor 28 integrated in the substrate displacement stage 26. The wavefront deviation 48 can be specified by Zernike coefficients. Depending on the design, Zernike coefficients Z2 to Z36 and optionally further Zernike coefficients can find use to this end. The wavefront deviation 48 and thus the desired correction can also be represented by a targeted selection of Zernike coefficients.

In the present application, as described, for example, in paragraphs [0125] to [0129] of US 2013/0188246A1, the Zernike functions known from, for example, Chapter 13.2.3 of the textbook “Optical Shop Testing”, 2nd Edition (1992) by Daniel Malacara, ed. John Wiley & Sons, Inc., are designated with Zⱼ according to the so-called fringe ordering, wherein bⱼ are then the Zernike coefficients assigned to the respective Zernike polynomials (also called “Zernike functions”). The fringe ordering is visualized, for example, in Table 20-2 on page 215 of the “Handbook of Optical Systems”, Vol. 2 by H. Gross, 2005 Wiley-VCH Verlag GmbH & Co. KgaA, Weinheim. While the Zernike polynomials are denoted by Zⱼ, which is to say with a subscripted index j, the Zernike coefficients bⱼ are denoted in the context of this application by Zⱼ, which is to say with a normally positioned index, such as Z5 and Z6 for astigmatism, for example.

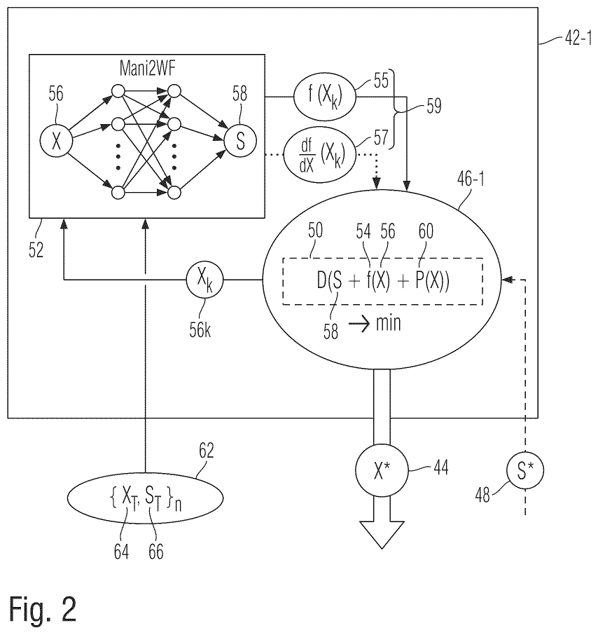

FIG. 2 illustrates a first embodiment 42-1 of the manipulator controller 42 according to FIG. 1. In this embodiment, the algorithm 46 is an optimization algorithm 46-1, which is configured to ascertain the travel command 44 by optimizing a target function 50, also referred to as a merit function. According to one embodiment, the target function 50 is as follows:

$$D ( S + f ( X ) + P ( X ) ) \qquad ( 1 )$$

Here, D is a metric, such as the square of the Euclidean norm ∥ ∥₂, S is a wavefront change 58 and is used to represent the wavefront deviation S* of the projection lens 22 in the target function 50, f(X) is a nonlinear sensitivity, denoted by the reference numeral 54, which represents a relationship between the travels x₁ to x₇, represented by the travel vector X, designated by the reference numeral 56, and the associated wavefront change 58 of the projection lens 22. P(X) represents optional regularization terms 60, which, for example, ensure that the travel amplitudes used for the wavefront correction also remain as small as possible.

According to one embodiment variant, the optimization algorithm 46-1 is configured to minimize the target function 50 and to determine the travel command X* resulting for the minimized target function 50:

$${X}^{*} = {arg min}_{X ∈ \overline{X}} D ( S + f ( X ) + P ( X ) ) . \qquad ( 2 )$$

Manipulated variable limits X̅ of the manipulators can thus likewise be integrated into the equation.

The optimization algorithm 46-1 optimizes the target function 50 iteratively, i.e. the travel vector X is changed step by step and the associated value of the target function 50 is ascertained. The manipulator controller 42-1 is configured to ascertain for each iteration the appropriate value 55 of the sensitivity f(X) using a neural network 52, i.e. for the travel vector Xₖ (reference sign 56k) valid for an iteration step k, to ascertain the assigned value f(Xₖ) of the wavefront change S.

Optionally, it is further possible to ascertain the gradient 57 of the nonlinear sensitivity f(X) for the travel vector Xₖ, i.e.

$$\frac{df}{dX} ( {X}_{k} ) ,$$

by way of the neural network 52. The sensitivity value f(Xₖ) is also denoted by the reference sign 55 and the sensitivity gradient

$$\frac{df}{dX} ( {X}_{k} )$$

by the reference sign 57. The sensitivity value 55 and the sensitivity gradient 57 are each a characteristic property of the target function 50, for example they are each a characteristic property of the parameter of the target function 50 represented by the nonlinear sensitivity f(X).

The optimization algorithm 46-1 can be referred to as a travel ascertainment module of the manipulator controller 42-1 because of its function of ascertaining the travel command 44, and the neural network 52 can be referred to as a support module of the manipulator controller 42 because of its function of providing information (sensitivity value 55 and gradient 57) to support the optimization algorithm 46-1. It should be noted that these do not have to represent physically distinguishable modules within the manipulator controller 42-1, but can also serve merely as functional units.

The neural network 52 is configured to determine an associated wavefront change S (reference sign 58) from a travel vector X (reference sign 56) with travel specifications for the manipulators M1 to M7. In this case, the travel vector X is understood to mean the specification of concrete values for the vector elements, and the wavefront change S is understood to mean a concrete value or plurality of concrete values defining the resulting wavefront change. Elsewhere in this text, the terms travel vector X and wavefront change S are used for the corresponding mathematical variable.

Due to the described function of the neural network 52, of converting the travel vector X into the wavefront change S, the neural network 52 is also referred to as “Mani2WF”. In this case, “Mani” stands for “Manipulator” and “WF” stands for wavefront change.

The neural network 52 is illustrated in FIG. 2 by way of example with reference to two hidden layers and an output layer. The hidden layers each have a multiplicity of nodes, and the output layer has only one node, wherein the configuration of the connection edges between the individual nodes is formed during a teach-in or training process. The neural network 52 is a machine learning method based on artificial intelligence. The architecture illustrated in FIG. 2 should be understood to be only an example, and other architectures can also be used.

By determining the wavefront change S assigned to the travel vector Xₖ of the respective iteration step k of the optimization algorithm 46-1, the neural network 52 ascertains the aforementioned sensitivity value f(Xₖ) (reference sign 55). Furthermore, it is possible to form the derivative of f(X) from the neural network as desired and thus to ascertain the sensitivity gradients

$$\frac{df}{dX} ( {X}_{k} )$$

denoted by the reference sign 57. In other words, the neural network generates the sensitivity value 55 and, if desired, the sensitivity gradient 57 as the ascertainment result 59.

The optimization algorithm 46-1 adopts the sensitivity value 55 obtained from the neural network 52 as the value of the wavefront change S or the sensitivity gradient 57 also obtained from the neural network 52 as the gradient of the nonlinear sensitivity f. While the sensitivity value 55 serves to calculate the value of the target function 50 at the respective iteration step k, the sensitivity gradient 57 enables the optimization algorithm 46-1 to decide in which direction the travel vector X is to move in the next iteration step.

According to one embodiment, the optimization algorithm 46-1 uses a gradient-based method, such as a gradient descent method, in which in each iteration step the sensitivity gradient 57 ascertained using the neural network 52 is used to improve the current solution. In addition, the gradient-based method uses the relevant sensitivity value 55. The nonlinear sensitivity f(X) is therefore linearized locally. The use of the neural network 52 enables this approach to be efficient in the first place, as it can directly supply the gradients of the nonlinear sensitivity f(X), in contrast to a simulation based on a finite element calculation (FEM simulation), and is also many times faster when calculating the sensitivity due to the calculation method.

According to a further embodiment, the optimization algorithm 46-1 is configured as a statistical search method or as a deterministic, gradient-free algorithm, such as a Nelder-Mead method. In this case, the optimization algorithm 46-1 usually involves only the sensitivity value 55. Statistical search methods and deterministic, gradient-free algorithms are generally known to a person skilled in the art. These do not require gradient values for the sensitivity.

In the Nelder-Mead method, the respective value for the wavefront deviation S is determined in a first iteration step for a specified number of, e.g. ten, widely spread vector values Xₖ of the travel vector 56. A vector value is selected therefrom and in the following iteration step, the respective value for the wavefront deviation is determined again for a specified number of, e.g. ten, vector values Xₖ. These vector values are no longer as widely spread as the vector values of the first iteration step, but lie within a narrow vicinity of the selected vector value. Further iteration steps are performed analogously, i.e. the spread of the vector values is narrower with each step than in the previous step.

In the above-mentioned teach-in process, the neural network 52 is taught using training data sets 62. Each of the training data sets 62 comprises a training travel vector X_{T}, also denoted by the reference sign 64, and an associated training wavefront change S_{T}, which is also denoted by the reference sign 66. In total, n such pairs are provided of in each case a training travel vector X_{T} and an associated training wavefront change S_{T} for teaching the neural network.

Each training travel vector 64 comprises a set of manipulator travels x₁ to x₇. These can be randomly selected or determined by a system. The training wavefront change 66 assigned to the respective training travel vector 64 can be ascertained by simulation or using previously carried out measurements and can be provided in the same format as the wavefront deviation 48, i.e., for example, in the form of the Zernike coefficients Z2 to Z36.

In the teach-in process, free parameters of the neural network 52 are adapted so that the neural network 52 defines the n data pairs of the training data sets 62 as precisely as possible and can also make predictions of the wavefront change for unknown manipulator travels not present in the training data sets 62. In a second step, the underlying metric is then iteratively optimized with an algorithm of choice using the neural network 52 trained in the first step and taking into account all boundary conditions until the solution converges to an optimum.

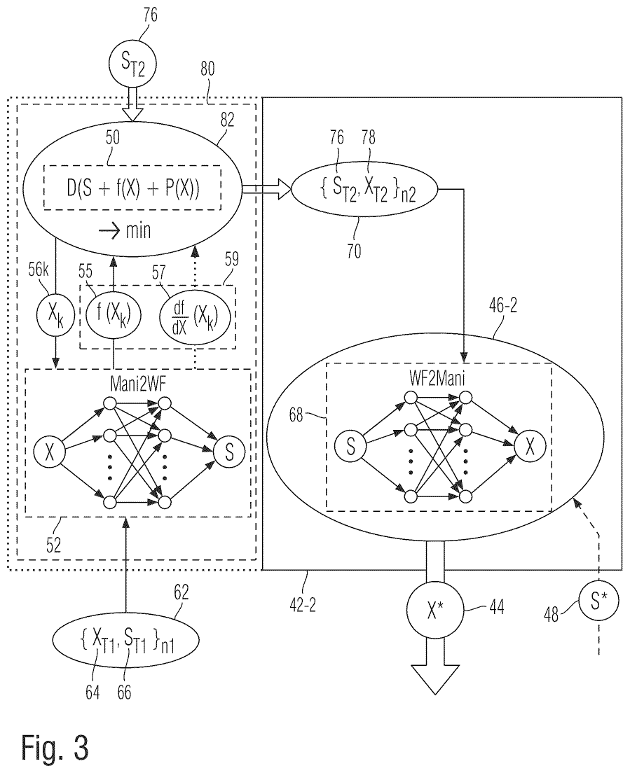

FIG. 3 illustrates a second embodiment 42-2 of the manipulator controller 42 according to FIG. 1. This embodiment 42-2 comprises an embodiment 46-2 of the algorithm 46, which is configured to ascertain the travel command 44 from the wavefront deviation 48 using a further neural network 68.

The neural network 68 is configured to determine from a wavefront change S an associated travel vector X with travel specifications for the manipulators M1 to M7. Thus, its function is inverse to the function of the neural network 52 designated “Mani2WF”. The neural network 68 is thus also referred to as “WF2Mani”. The algorithm 46-2 is configured in the illustrated embodiment to implement the neural network 68 and thus to ascertain the travel command X* from the wavefront deviation S* serving as input data set using the neural network 68. The neural network 68 may be identical to the algorithm 46-2, i.e. the algorithm 46-2 is configured as the neural network 68. Analogous to the illustration of the neural network 52 in FIG. 2, the neural network 68 in FIG. 3 is illustrated using two hidden layers and an output layer. The neural network 68 is likewise a machine learning method which is based on artificial intelligence and is taught or trained.

The neural network 52 corresponds to the neural network already described with regard to FIG. 2, which is configured to determine a wavefront change S from a travel vector X and is thus referred to as “Mani2WF”. In the embodiment according to FIG. 3, training data sets 70 serving for training the neural network 68 are generated using the neural network 52.

Analogous to the optimization algorithm 46-1 according to FIG. 2, the algorithm 46-2 can be referred to as the travel ascertainment module of the manipulator controller 42-2 because of its function of ascertaining the travel command 44. Furthermore, the manipulator controller comprises a support module 80 for supporting the algorithm 46-2 by providing the training data sets 70. Here, it is also to be noted that the travel ascertainment module 46-2 and the support module 80 do not need to constitute physically distinguishable modules within the manipulator controller 42-2, but can also serve merely as functional units.

The support module 80 comprises the neural network 52 and an optimization algorithm 82. The optimization algorithm 82 generates associated training travel vectors X_{T2} (reference sign 78) for a large number of specified training wavefront changes S_{T2} (reference sign 76). Each training travel vector 78 comprises a set of manipulator travels x₁ to x₇.

In total, n2 such pairs of in each case a training wavefront change S_{T2} and an associated training travel vector X_{T2} are provided by the support module 80 as training data set 70 for teaching the neural network 68.

The generation of a training travel vector X_{T2} from a specified training wavefront change S_{T2} by the optimization algorithm 82 in combination with the neural network 52 of the support module 80 takes place analogously to the above-described generation of the travel command 44 from the wavefront deviation 48 by way of the optimization algorithm 46-1 in combination with the neural network 52 of the manipulator controller 42-1 according to FIG. 2.

The optimization algorithm 80 optimizes a target function 50 iteratively, which can be configured identically to the target function 50 according to FIG. 2, i.e. the travel vector X is changed step by step and the associated value of the target function 50 is ascertained. The support module 80 is configured to ascertain for each iteration the appropriate value 55 and, if desired, the gradient 57 of the nonlinear sensitivity f(X) using the neural network 52, i.e. for the travel vector Xₖ (reference sign 56k) valid in an iteration step k, to ascertain the assigned value f(Xₖ) and, if desired, the sensitivity gradient u(Xₖ) of the wavefront change S.

The sensitivity value 55 and the sensitivity gradient 57 are each a characteristic property of the target function 50, for example they are each a characteristic property of the parameter of the target function 50 represented by the nonlinear sensitivity f(X). The ascertained value 55 and optionally the sensitivity gradient 57 are used in the execution of the optimization algorithm 80, as described above with reference to the optimization algorithm 46-1.

The sequence shown in FIG. 3 represents a training approach of the second neural network 68 which is referred to as supervised learning, i.e. the solution is already determined before the training. Alternatively, the second neural network 68 can also be trained via an approach of unsupervised learning, in which the neural network 68 independently learns to optimize training wavefront changes S_{T2} (reference sign 76) with regard to the target function 50 and to determine the associated travel vector X_{T2}, i.e. the solution is ascertained only during training.

The support module 80 and thus the neural network 52 may be part of the manipulator controller 42-2 and thus part of the projection exposure apparatus 10. In this configuration, new training data sets 70, i.e. training data sets adapted to new boundary conditions, can be provided by the support module 80 at regular intervals.

Alternatively, the support module can be physically run as a separate computing unit. The training data sets 70 are then made available to the manipulator controller 42-2 of the projection exposure apparatus 10 for teaching the neural network 68. This is usually done before the start of commissioning of the projection exposure apparatus 10 for the production of semiconductor devices. Furthermore, new training data sets 70 can be read into the manipulator controller 42-2 at specific times, such as during maintenance interruptions of the production process, and the neural network 68 can thus be adapted to new boundary conditions, for example.

The neural network 52 (“Mani2WF”) is also trained or taught. This is done, analogously to the teach-in process already described with reference to FIG. 2, using training data sets 62. The training data sets each comprise a training travel vector 64, which in this embodiment is referred to as X_{T1}, and an associated training wavefront change 66, which in this embodiment is referred to as S_{T1}. In total, n1 such pairs are provided of in each case a training travel vector X_{T1} and an associated training wavefront change S_{T1} for teaching the neural network 52. As already described in reference to FIG. 2, the training wavefront change 66 assigned to a respective training travel vector 64 can be ascertained by simulation or using previously carried out measurements.

The above description of exemplary embodiments, embodiments or embodiment variants should be understood to be by way of example. The disclosure effected thereby firstly enables the person skilled in the art to understand the present disclosure and the features associated therewith, and secondly encompasses alterations and modifications of the described structures and methods that are also obvious in the understanding of the person skilled in the art. Therefore, all such alterations and modifications, insofar as they fall within the scope of the disclosure in accordance with the definition in the accompanying claims, and equivalents are intended to be covered by the protection of the claims.

### LIST OF REFERENCE SIGNS

10 Projection exposure apparatus
12 Exposure radiation source
14 Exposure radiation
16 Illumination system
18 Mask
20 Mask displacement stage
22 Projection lens
23 Exposure beam path
24 Substrate
26 Substrate displacement stage
28 Wavefront sensor
30 Manipulation apparatus
32 Mirror surface
34 Heating radiation
36h Local zone with high irradiation intensity
36g Local zone with lower irradiation intensity
38 Cross section of the exposure beam path
40 Tilt axis
42 Manipulator controller
44 Travel command
46 Algorithm
46-1 Optimization algorithm
46-2 Algorithm
48 Wavefront deviation S*
50 Target function
52 Neural network
54 Nonlinear sensitivity
55 Sensitivity value
56 Travel vector
56k Travel vector at an iteration step
57 Sensitivity gradient
58 Wavefront change S
59 Ascertainment result
60 Regularization terms
62 Training data sets
64 Training travel vector X_{T}
66 Training wavefront change S_{T}
68 Neural network
70 Training data sets
72 Training wavefront change S_{T1}
74 Training travel vector X_{T1}
76 Training wavefront change S_{T2}
78 Training travel vector X_{T2}
80 Support module
82 Optimization algorithm
M1 to M7 Manipulators
R1 to R4 Mirrors
x₁ to x₇ Travels
X₁* to x₇* Travel specifications

What is claimed is:

1. An apparatus, comprising:
a projection lens, comprising:
a plurality of optical elements configured to image on object field into an image field; and
a plurality of manipulators, each manipulator assigned to one of the optical elements and configured to change an optical effect of the assigned optical element by manipulating a property of the optical element along a travel; and
a controller configured to:
ascertain a travel command with travel specifications for the manipulators to correct a wavefront deviation of the projection lens;
ascertain an associated wavefront change of the projection lens from a travel vector with a set of manipulator travels via a neural network; and
determine the travel command using an ascertainment result of the neural network from the wavefront deviation, and
wherein the apparatus is a microlithographic projection exposure apparatus.

2. The apparatus of claim 1, wherein the controller is configured to determine the travel command by optimizing a target function and to use the ascertainment result of the neural network in the optimization.

3. The apparatus of claim 2, wherein the target function has a nonlinear sensitivity defining a relationship between the travel vector and the associated wavefront change of the projection lens, and wherein the ascertainment result comprises a gradient of the nonlinear sensitivity.

4. The apparatus of claim 3, wherein the ascertainment result further comprises a value of the nonlinear sensitivity.

5. The apparatus of claim 2, wherein the controller is configured to effect an optimization of the target function iteratively and to update the ascertainment result with each iteration and to determine the at least one characteristic property of the target function based on the updated ascertainment result of the neural network.

6. The apparatus of claim 1, wherein the controller is configured to use a gradient-based method.

7. The apparatus of claim 1, wherein the controller is configured to use a statistical search method or as a deterministic, gradient-free method, and wherein the at least one characteristic property comprises a value of the wavefront change.

8. The apparatus of claim 1, wherein the manipulator controller is configured to ascertain training data sets generated via the ascertainment result of the neural network and to train a further neural network therewith, and wherein the controller is configured to ascertain the travel command from the wavefront deviation via the further neural network.

9. The apparatus of claim 8, wherein the manipulator controller is configured to determine the training data sets by optimizing a target function and to use the ascertainment result of the first neural network in the optimization.

10. The apparatus of claim 8, wherein boundary conditions for the travel command ascertained via the further neural network are created using the training data sets.

11. The apparatus of claim 1, wherein at least one part of the manipulators is assigned to the same optical element and is configured to change the temperature of different sections of this optical element.

12. The apparatus of claim 1, further comprising a wavefront measuring device configured to ascertain the desired correction on the wavefront.

13. The apparatus of claim 1, wherein the apparatus has an operating wavelength in the EUV wavelength range or DUV wavelength range.

14. A method of operating a microlithographic projection exposure apparatus comprising a projection lens a plurality of optical elements configured to image an object field into an image field, the microlithographic projection exposure apparatus further comprising a plurality of manipulators, each of which is assigned to one of the optical elements and configured to change an optical effect of the assigned optical element by manipulating a property of the optical element along a travel, the method comprising:
determining a wavefront deviation of the projection lens;
ascertaining a wavefront change of the projection lens from a travel vector with a set of manipulator travels using a neural network; and
determining a travel command with travel specifications for the manipulators from the wavefront deviation using an ascertainment result of the neural network.

15. The method according to claim 14, wherein a target function is optimized during the determination of the travel command and the ascertainment result of the neural network is used in the optimization.

16. The method according to claim 15, wherein training data sets are ascertained via the ascertainment result of the neural network and a further neural network is trained therewith, by which the travel command is ascertained from the wavefront deviation.

17. The method according to claim 14, wherein training data sets are ascertained via the ascertainment result of the neural network and a further neural network is trained therewith, by which the travel command is ascertained from the wavefront deviation.

18. One or more machine-readable hardware storage devices comprising instructions that are executable by one or more processing devices to perform operations comprising the method of claim 14.

19. A system, comprising:
one or more processing devices; and
one or more machine-readable hardware storage devices comprising instructions that are executable by one or more processing devices to perform operations comprising
the method of claim 14.

20. The system of claim 1, further comprising:
a microlithographic projection exposure apparatus, comprising:
a projection lens a plurality of optical elements configured to image mask structures; and
a plurality of manipulators, each of which is assigned to one of the optical elements and configured to change an optical effect of the assigned optical element by manipulating a property of the optical element along a travel.
